(19) United States
(12) Patent Application Publication
(10) Pub. No.: US 2012/0067425 A1
(43) Pub. Date: Mar. 22, 2012

(54) ALUMINUM BASE MATERIAL, METAL SUBSTRATE HAVING INSULATING LAYER EMPLOYING THE ALUMINUM BASE MATERIAL, SEMICONDUCTOR ELEMENT, AND SOLAR BATTERY

(75) Inventors: Shigenori Yuuya, Kanagawa-ken (JP); Ryouzou Kaito, Kanagawa-ken (JP); Hirokazu Sawada, Kanagawa-ken (JP)

(73) Assignee: FUJIFILM CORPORATION, Minato-Ku, Tokyo (JP)

(21) Appl. No.: 13/319,353

(22) PCT Filed: May 7, 2010
(86) PCT No.: PCT/JP2010/058148

§ 371 Date: Nov. 8, 2011

(30) Foreign Application Priority Data
May 8, 2009 (JP) 2009-113673

(51) Int. Cl. H01L 31/0264; C22C 21/00; C22C 21/06; C25D 5/44; B32B 15/04; H01L 31/02; H01L 31/0272; H01L 29/40; C25D 7/00

(52) U.S. Cl. 136/262; 257/734; 420/528; 420/542; 205/50; 136/252; 136/265; 136/264; 205/207; 257/E29.111

(57) ABSTRACT

A metal substrate with an insulating layer, which is capable of being produced by a simple process, exhibits heat resistance during semiconductor processing, is superior in voltage resistance, and has small leakage current, and an Al base material that realizes the metal substrate are provided. The metal substrate with an insulating layer is formed by administering anodic oxidation on at least one surface of the Al base material. The Al base material includes only precipitous particles of a substance which is anodized by anodic oxidation as precipitous particles within an Al matrix.

### BACKGROUND OF THE INVENTION

1. Field of the Invention

The present invention is related to an Al base material for forming a metal substrate with an insulating layer for an semiconductor element, in which an anodized film is the insulating layer, the metal substrate with the insulating layer, the semiconductor element, and a solar battery.

2. Description of the Related Art

There have been recent advancements in forming semiconductor elements such as solar batteries and TFT's (Thin Film Transistors) to be flexible and lightweight. Flexible devices may be applied to a wide variety of uses, such as for electronic paper, flexible displays, and the like.

Glass substrates had been primarily used as substrates of semiconductor elements, because of requirements such as insulating properties with respect to semiconductor circuits formed thereon, and heat resistance properties that enable the substrate to withstand forming temperatures of semiconductor films having superior element properties. However, glass substrates are fragile, and poor in flexibility. Therefore, it is difficult to form thin, lightweight glass substrates.

For this reason, substrates formed of metal, such as Al and stainless steel, on which insulating films are provided, are being considered as lightweight substrates, which are superior to conventional glass substrates in flexibility and are capable of withstanding high temperature processing. As described above, it is necessary for semiconductor circuits and substrates to be insulated from each other. Insulating films are required to have small leakage current (high resistance), high voltage resistance, and to not have insulation failures due to voltages which are applied during use.

For example, in CIGS solar batteries, the voltage generated by each individual solar battery cell is approximately 0.65V at most. However, modular circuits, in which close to 100 cells are connected in series on a single substrate, are common. If safety and reliability over long periods of time are considered, voltage resistance for voltages of 500V or greater is necessary for an insulating layer of a metal substrate. In addition, even if insulation failure does not occur, the photoelectric conversion efficiency of the solar battery module will decrease if leakage currents are present.

Japanese Unexamined Patent Publication No. 2001-339081 discloses a CIGS solar battery that employs a substrate, in which insulating layers are provided on both sides of a conductive base. The substrate of Japanese Unexamined Patent Publication No. 2001-339081 is obtained by forming oxidized films on the metal base by the vapor phase method or the liquid phase method. This leads to pinholes, cracks, and the like being easily formed in the oxidized film. In addition, from the viewpoint of adhesive properties, the oxidized film is likely to become separated from the metal base during semiconductor processing. Due to these drawbacks, it is difficult to obtain a semiconductor element having favorable element properties.

Meanwhile, administering an anodic oxidation process onto the surface of an Al substrate, and employing the Al substrate, on the surface of which a porous AAO (Anodized Aluminum Oxide) film is formed, has also been proposed. Such a substrate is constituted by an insulating layer formed by the anodized portion, and a metal layer (Al layer) formed by the non anodized portion that remains without being anodized. Therefore, the adhesive properties between the insulating layer and the metal layer are favorable, and a substrate having a large area can be obtained by a single processing step. However, AAO films are porous, and therefore the insulation properties thereof are not high. Accordingly, techniques for improving the insulation properties of AAO films, and techniques for compensating for deteriorations in element properties caused due to poor insulation properties, have been proposed (Japanese Unexamined Patent Publication Nos. 2000-049372, 7 (1995) -147416, and 2003-330249).

Japanese Unexamined Patent Publication No. 2000-049372 proposes to increase light utilization efficiency by providing uneven structures on the surface of a substrate, thereby improving element properties. Japanese Unexamined Patent Publication No. 7(1995)-147416 discloses a liquid crystal matrix panel, in which the surface of an AAO film is further covered by an SiN film, to improve insulation properties. Japanese Unexamined Patent Publication No. 2003-330249 proposes to cause the thickness of a barrier layer, which is an alumina layer between the bottoms of the fine pores of a porous portion and the Al base, to become thicker with a pore filling method, in order to improve insulation properties.

Japanese Unexamined Patent Publication No. 2000-049372 improves the element properties with the uneven structures formed on the substrate surface. However, the insulation properties per se are not improved, and the problems associated with voltage resistance and leakage current still remain. In addition, the methods proposed in Japanese Unexamined Patent Publication Nos. 7(1995)-147416 and 2003-330249 require further processes after formation of the AAO film.

### SUMMARY OF THE INVENTION

The present invention has been developed in view of the foregoing circumstances. It is an object of the present invention to provide a metal substrate having an insulating layer which is capable of being produced by a simple process, has heat resistance during semiconductor processing, is superior in voltage resistance, and has small leakage current. It is another object of the present invention to provide an Al base material that realizes the metal substrate.

Still another object of the present invention of the present invention is to provide a semiconductor element and a solar battery that employs the metal substrate having an insulting layer.

The present inventor investigated the leakage current properties and factors that deteriorate the voltage resistance properties of Al substrates equipped with anodized films on the surfaces thereof (hereinafter, referred to as AAO (Anodized Aluminum Oxide) substrates), which are employed as substrates for semiconductor elements. As a result of the investigations, the inventor succeeded in discovering a novel design concept for a substrate for a semiconductor element which is superior in leakage current properties and voltage resistance properties. The present inventor invented a substrate for a semiconductor element which is superior in leakage current properties and voltage resistance properties, an Al base material that realizes the substrate for a semiconductor element, and a semiconductor element employing the substrate for a semiconductor element, based on the novel design concept.

That is, an Al base material of the present invention is that to be utilized in a method for forming a metal substrate with an insulating layer for a semiconductor element, by performing anodic oxidation on at least one surface thereof, characterized by:

precipitous particles of only a substance which is capable of being anodized by anodic oxidation being included as precipitous particles within an Al matrix (unavoidable impurities may be included).

Here, the Al base material may be pure Al, pure Al crystals having fine amounts of solid solute elements of unavoidable impurities, or an alloy matrix of Al and fine amounts of another metal element, in which precipitous particles are included. The amount of precipitous particles and elements of unavoidable impurities included within the Al matrix is 10 weight % or less of the Al base material.

The term “precipitous particles” refers to crystals having different crystal structures from that of the Al matrix, and amorphous substances in particulate form. For example, wrought aluminum for industrial use includes fine amounts of impurities. As a result of the impurities exceeding the solid solute limit, intermetallic compounds of the insure components and Al, or metal particles such as metallic Si become eccentrically located to form the precipitous particles. Commonly known examples of precipitous particles include: stable phase intermetallic compounds such as metallic Si, Al₃Mg₂, Al₃Fe, Mg₂Si, CuAl₂, and Al₆Mn; and depending on refining conditions during heating processes, metastable intermetallic compounds such as α-AlFeSi and Al₆Fe.

Metallic Si within the Al base material is conductive Si, in which an extremely fine amount of impurities is solidly dissolved within Si crystals.

The phrase “precipitous particles of only a substance which is capable of being anodized by anodic Oxidation being included” refers not only to a state in which all of the precipitous particles present within the Al base material are anodized precipitous particles, but also includes a state in which non anodized precipitous particles are present within a range that practically enables the objective of the present invention to be met. Here, the phrase “a range that practically enables the objective of the present invention to be met” may be set as appropriate, according to the particle size of the non anodized precipitous particles, or according to the number of particles per unit sectional area.

Hereinafter, the precipitous particles of the substance which is anodized during anodic oxidation of the Al base material will be referred to as “anodized precipitous particles”, and the precipitous particles of a substance which is not anodized during anodic oxidation of the Al base material will be referred to as “non anodized precipitous particles”.

In the Al base material of the present invention, it is preferable for the substance which is anodized to be an intermetallic compound that includes one of Al and Mg.

In the Al base material of the present invention, it is preferable for metallic Si to be substantially not included as precipitous particles within the Al base material.

Here, that metallic Si precipitous particles are “substantially not included” refers to cases in which the presence of metallic Si precipitous particles cannot be confirmed when the surface of the Al base material is analyzed with am EPMA (Electron Probe Micro Analyzer). That is, precipitous particles which are smaller than the spatial resolution capable of being detected by the EPMA will not be observed, however, amounts of metallic Si to such a degree are allowable. Of course, it is preferable for absolutely no metallic Si precipitous particles to be included, and therefore, it is desirable for the amount of metallic Si to be controlled such that it is less than or equal to a smaller amount which can be confirmed by a different analysis method.

Note that in the case that polishing agents that include Si such as SiO₂ and SiC are utilized on substrates, the polishing agents may become embedded into the soft Al matrix of the substrates. There is a possibility that such embedded polishing agents will be erroneously detected as metallic Si. Therefore, substrates may be immersed in an NaOH solution to dissolve the surface of the Al, separate and remove the embedded polishing agents, cleansed, and then observed.

A metal substrate having an insulating layer of the present invention is that in which an anodized film is formed on at least one surface of the aforementioned Al base material, by anodic oxidation being performed on the at least one surface of the Al base material.

A semiconductor element of the present invention is characterized by comprising: the metal substrate having an insulating layer of the present invention; a semiconductor layer provided on the metal substrate; and at least one pair of electrodes for applying voltages to the semiconductor layer.

It is preferable for the semiconductor element of the present invention to be of a configuration, in which: the semiconductor is a photoelectric converting element that has a photoelectric converting function, in which electric currents are generated by the semiconductor layer absorbing light. It is preferable for the main component of the semiconductor layer to be a compound semiconductor having at least one type of chalcopyrite structure. It is preferable for the compound semiconductor of the chalcopyrite structure to be at least one type of compound semiconductor comprising Ib group elements, IIIb elements, and VIb elements. At least one Ib group element may be selected from a group consisting of Cu and Ag; at least one IIIb group may be element selected from a group consisting of Al, Ga, and In; and at least one VIb group element may be selected from a group consisting of S, Se, and Te.

In the present specification the term “main component” refers to a component which is included at 90 weight o or greater.

A solar battery of the present invention is characterized by being equipped with the photoelectric converting semiconductor element of the present invention.

Japanese Unexamined Patent Publication No. 2002-241992 discloses an anodized aluminum alloy part for a surface processing apparatus, which is superior in voltage resistance, that defines the number of bulky intermetallic compounds included within an anodized film per square millimeter. In the invention of this document, a correlation was discovered between abnormal electrical discharge that occurs due to low voltage resistance of parts within a surface processing apparatus that generates fluorine plasma in the interior thereof, and the number of bulky intermatllic compounds within an anodized film. Therefore, the invention of this document defines an upper limit value for the number of bulky intermetallic compounds per square millimeter of the anodized film.

In this document, the intermetallic compounds which are present within a material and are included in the anodized film include those that were only slightly oxidized during an anodic oxidation process, and remain in a substantially metallic state, and those that dissolve during the anodic oxidation process and form holes in the film. Although the degrees of influence are different between the two, these two factors affect voltage resistance, and become causes for the abnormal electric discharge (refer to paragraph [0011], etc.).

The electrical property required for a part of a surface processing apparatus that generates fluorine plasma is voltage resistance to a degree capable of suppressing abnormal electrical discharge during generation of the fluorine plasma, as described above. On the other hand, the electrical properties required for the substrate for semiconductor elements of the present invention are leakage current properties that lead to favorable element properties, and highly reliable voltage resistance.

As described above, the present inventors discovered that the insulation properties of the barrier layer at the bottom portion of an anodized film of an AAO substrate for semiconductor elements are most important in determining leakage current properties and voltage resistance properties. That is, it was discovered that the insulation properties of the barrier layer have great influence on the leakage current properties and voltage resistance properties of the AAO substrate for semiconductor elements. In addition, it was discovered that anodized intermetallic compounds present within the anodized film do not form dissolved holes, but become an irregular porous layer, and that the irregular porous layer has very little influence on the insulation properties of the anodized film. Details related to these discoveries will be described later.

Japanese Unexamined Patent Publication No. 2002-241992 is silent regarding leakage current properties. In addition, the discussion regarding the presence ratio of intermetallic compounds is performed with respect to the anodized film as a whole, and that the insulation properties of the barrier layer is most important is neither disclosed nor suggested. Accordingly, the invention of the present application is completely different in structure, and has a completely different objective from the invention disclosed in Japanese Unexamined Patent Publication No. 2002-241992.

The present invention provides a novel design concept for an Al substrate having an anodized film on the surface thereof (AAO substrate), which is employed as the substrate of a semiconductor element, having superior leakage current properties and voltage resistance properties. According to the present invention, a metal substrate having an insulating layer which is capable of being produced by a simple process, has heat resistance during semiconductor processing, is superior in voltage resistance properties, and has small leakage current, can be obtained.

The Al base material of the present invention includes precipitous particles of only a substance which is capable of being anodized by anodic oxidation as precipitous particles within the Al matrix. Therefore, if a metal substrate having an insulating layer is formed by administering anodic oxidation on the Al base material, the precipitous particles which are taken into the anodized film during anodic oxidation are only insulating particles which are obtained by being anodized along with the Al base material. Accordingly, a metal substrate having an insulating layer obtained using the Al base material does not include conductive precipitous particles that greatly reduce insulation properties in the barrier layer at the bottom of the insulating layer. Therefore, the voltage resistance of the insulating layer becomes high, and a metal substrate having an insulating layer that exhibits low leakage current can be realized.

A semiconductor element that employs the metal substrate having an insulating layer of the present invention is a highly durable semiconductor element capable of maximally utilizing the properties of the semiconductor element (such as the photoelectric conversion properties), because the voltage resistance properties of the insulating layer and the leakage current properties are favorable.

### BRIEF DESCRIPTION OF THE DRAWINGS

FIG. 1 is a graph that illustrates the current-voltage properties of an AAO substrate obtained by anodizing a highly pure Al substrate (Al-polarity).

FIG. 2 is a diagram that illustrates an enlarged view of one pore of a porous layer.

FIG. 3A is a schematic sectional diagram that illustrates the structure of an Al substrate according to a first embodiment of the present invention.

FIG. 3B is a schematic sectional diagram that illustrates the structure of a metal substrate having an insulating layer, which is obtained by anodizing the Al substrate of FIG. 3A.

FIG. 4A is a schematic sectional diagram that illustrates the structure of an Al substrate that includes metal precipitous particles.

FIG. 4B is a schematic sectional diagram that illustrates the structure of a metal substrate having an insulating layer, which is obtained by anodizing the Al substrate of FIG. 4A.

FIG. 5 is a schematic sectional diagram that illustrates a semiconductor element according to a second embodiment of the present invention.

FIG. 6 is a graph that illustrates the relationships among the lattice constants of I-III-VI compound semiconductors and bandgaps.

FIG. 7 is an electron microscope photograph of a metal substrate having an insulating layer having anodized precipitous particles, of Embodiment 2.

FIG. 8A is a graph that illustrates the excess current properties of Embodiment 1.

FIG. 8B is a graph that illustrates the excess current properties of Embodiment 2.

FIG. 8C is a graph that illustrates the excess current properties of Comparative Example 1.

### DESCRIPTION OF THE PREFERRED EMBODIMENTS

### [Al Base Material and Metal Substrate Having an Insulating Layer]

The present invention is related to an Al substrate having an anodized film, which is obtained by partially anodizing the surface of an Al base material, for use as a metal substrate having an insulating layer for semiconductor elements. The present invention is also related to an industrial Al base material which is capable of producing the Al substrate having the anodized film. The present inventor investigated the factors that cause deterioration in the insulation properties of Al substrates having anodized films (hereinafter, referred to as AAO substrates). As a result, it was found that the insulation properties of the barrier layers at the bottom portions of anodized films of AAO substrates are important. It was also found that the insulation properties of AAO substrates greatly deteriorate due to the presence of non anodized precipitous particles, which are not anodized during anodic oxidation and remain as metals, form among unavoidable impurities included in Al base materials.

First, the present inventor employed aluminum having a purity of 99.99% or greater, such as that employed in JIS1N99, to remove the influence of unavoidable impurities, and produced an AAO substrate therefrom. Then, the voltage resistance properties of the AAO substrate were measured. The method for producing the Al material is as follows. A solution was prepared employing the aluminum having a purity of 99.99% or greater, such as that employed in JIS1N99, and solution heat treatment and filtration were performed, to produce an ingot having a thickness of 500 mm and a width of 1200 mm by the DC casting method. The surface of the ingot was milled for an average thickness of 10 mm by a surface miller. Then, isothermal heating was performed for approximately five hours at 550° C. When the temperature decreased to 400° C., the ingot was rolled by a hot rolling mill to form a rolled plate having a thickness of 2.7 mm. Further, the heat treatment was performed at 500° C. for one hour by an annealing device, and the rolled plate was finished to have a thickness of 0.24 mm by cold rolling employing a mirror finished roll.

The surface of this Al material was ultrasonically cleansed with ethanol, then electrolytically polished with a mixed solution of acetic acid and perchloric acid. Then, potentiostatic electrolysis at 40V was administered the Al plate within a 0.5mol/L oxalic acid solution, to form an anodized film having a thickness of 10 μm on the surface of the Al plate.

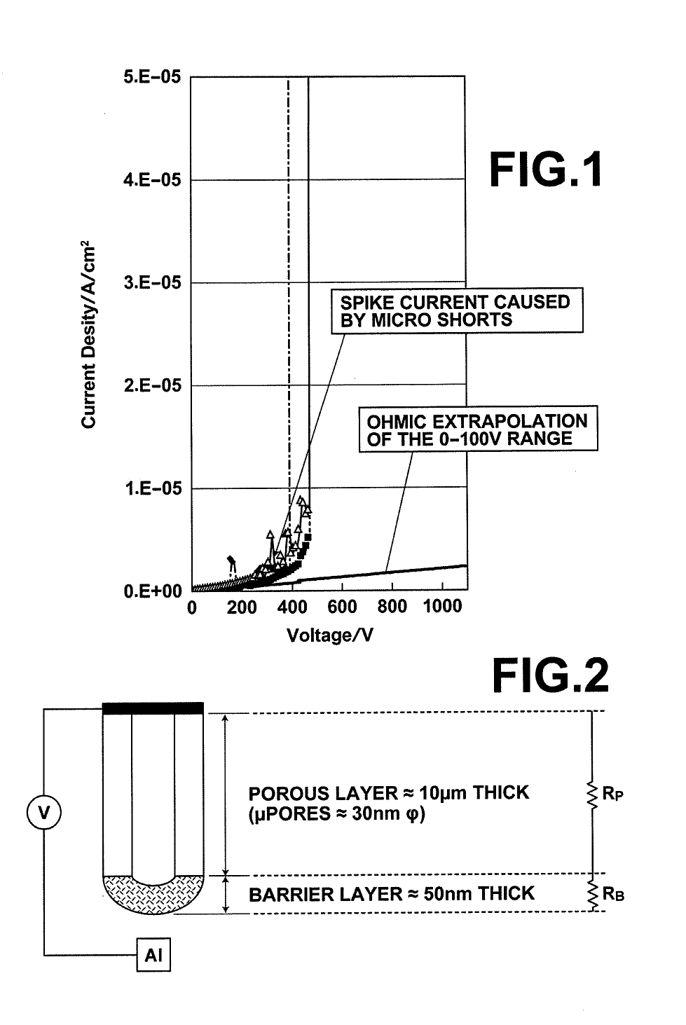

Leakage current of the obtained AAO substrate was measured, by applying a voltage having a negative polarity to the Al layer which was not anodized and remained. A 0.2 μm thick Au film having a diameter of 5 mmp was formed on the anodized surface by mask vapor deposition as an electrode. Voltage was applied between the Au electrode and the Al base material, to measure the current-voltage properties and the insulation failure voltage. Voltage was applied for one second in 10V steps, until insulation failure occurred. Here, values which were obtained by dividing the leakage current by the area of the Au electrode (9.6 mm²) were designated as the leakage current density. The results are illustrated in FIG. 1.

FIG. 1 is a graph that illustrates the current-voltage properties. The graph indicates that current begins to flow suddenly at approximately 200V, and that insulation failure occurs at approximately 400V. That is, it is considered that high resistance is exhibited up to approximately 200V, and that amounts of current based on the unique volume resistance of the barrier layer are flowing. On the other hand, large amounts of spike form currents are observed from approximately 200V to the insulation failure point. This is considered to be due to insulation failures occurring locally at electrically fragile portions of the barrier layer, which causes spike currents due to micro shorts, resulting in leakage currents. The number of locations of the barrier layer at which micro shorts occur increase accompanying the increase in voltage, and the amounts of micro short currents at each micropore increase, ultimately resulting in insulation failure of the AAO substrate as a whole, due to the material itself being destroyed by joule heat generation, which is a product of the leakage current and applied voltage. Note that FIG. 1 illustrates a plurality of current-voltage properties, which are measurement results obtained for the same AAO substrate using different Au electrodes.

From these results, it can be understood that once localized insulation failures begin to occur in the barrier layer, the amount of leakage current increases suddenly, and leads to insulation failure of the AAO substrate as a whole.

FIG. 2 is a diagram that illustrates an enlarged view of one pore of a porous layer, in a state in which voltage is being applied. When considered as an electrical circuit, this is a state in which voltage is being applied to a circuit constituted by a resistance RB of the barrier layer and a resistance RP of the porous layer connected in series.

If resistance R is calculated from the slope of the Ohmic region form 0V to 100V in FIG. 1, R=5.1·10⁸ Ωcm². If the fact that the thickness of the barrier layer is approximately 50 nm is taken into consideration, the volume resistance of the barrier layer of the AAO substrate is calculated to be approximately at the 10¹⁴ Ωcm level. In addition, based on the fact that the diameter of the pore is approximately 30 nm, the barrier layer resistance RB for each micro pore is calculated to be 10²⁰Ω. The resistance value of the surface of the AAO substrate was measured separately to be 10¹⁰Ω/□. Based on this value, the surface resistance RP of the inner walls of each micro pore within the porous layer is calculated to be 10¹²Ω, from 30 nmφ·10 μm. Accordingly, the sum of the resistance value of the barrier layer and the resistance value of the porous layer is the total resistance within a voltage region at which micro shorts do not occur. However, because the resistance value of the porous layer is significantly lower than that of the barrier layer, the resistance value of the barrier layer is the true resistance value. Meanwhile, in the case that insulation failure occurs in the barrier layer and micro shorts occur, the resistance of the barrier layer is substantially zero, and current flows according to the surface resistance RP of the inner walls of the micro pores.

From the above, it was confirmed that the influence of the barrier layer on the insulation properties related to leakage current properties and voltage resistance properties of the AAO substrate is great. Accordingly, it was also confirmed that it is preferable to employ substrates having barrier layers with favorable insulation properties as substrates for semiconductor elements.

Next, the present inventor investigated the influence of unavoidable impurities on the insulation properties of AAO substrates.

There are grades of Al purity in Al base materials. JIS1080 Al, which is commonly employed as a wrought industrial Al base material, has an Al purity of greater than 99.8%, and 0.15 weight % each of Si and Fe are allowable. JIS1100 Al has an Al purity of greater than 99.0%, and 0.95 weight % of Si and Fe are allowable. These unavoidable impurities are present as solid solutes within Al crystals of the Al matrix, and also as precipitous particles, which are elements that exceed the solid solute limit and become metals or intermetallic compounds.

Based on this knowledge, the present inventor thought that the influence of the presence of such precipitous particles on the insulation properties of AAO substrates differs depending on whether the precipitous particles are anodized, that is, whether they become insulators by anodic oxidation. The present inventor discovered that the absence of non anodized particles, particularly within barrier layers and the vicinities thereof, is extremely important with respect to the leakage current properties and the voltage resistance properties of AAO substrates.

That is, an Al base material 1 of a first embodiment includes precipitous particles 15 which were not capable of being solidly dissolved in the Al matrix, and the precipitous particles 15 are intermetallic compounds that become oxides by being anodized during anodic oxidation of the Al base material (hereinafter, referred to as anodized precipitous particles 15), from among the impurities included in the industrial Al base material.

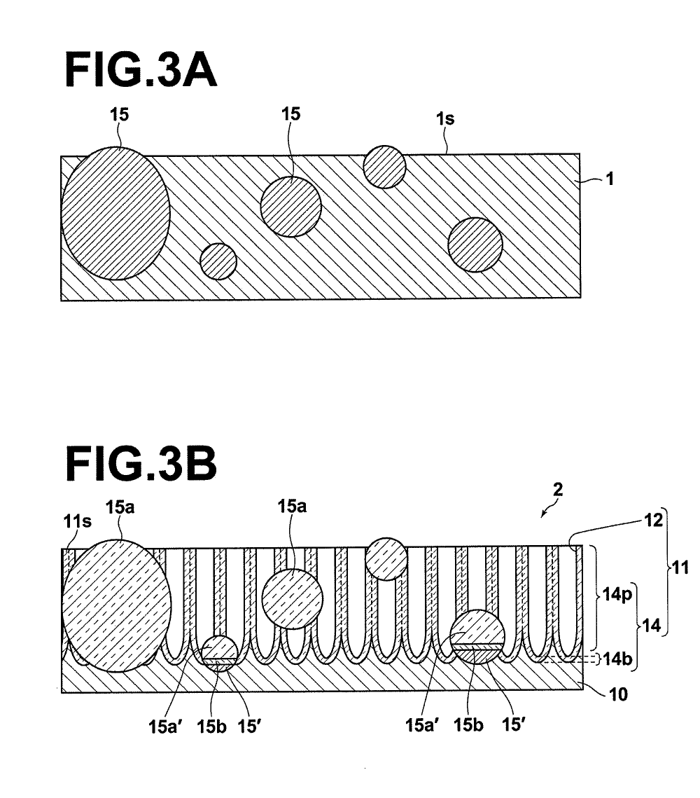

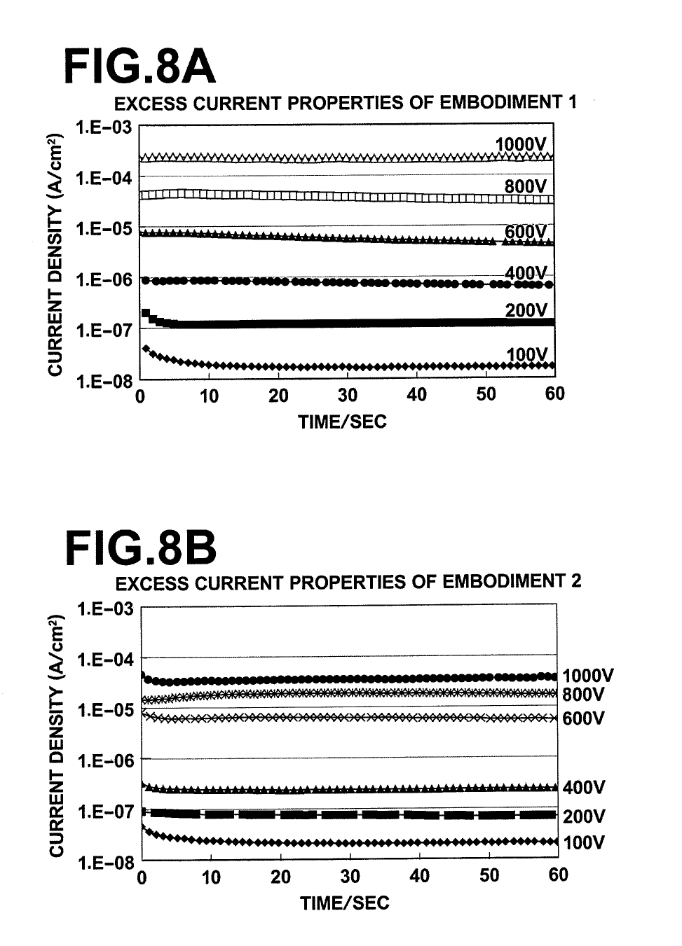

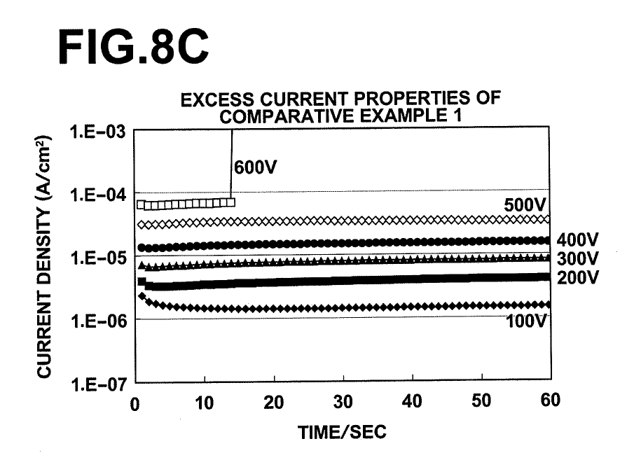

When the Al base material 1 illustrated in FIG. 3A is anodized from the surface is thereof, an anodized film 11 constituted by an anodized porous layer 14p, a barrier layer 14b, and fine pores 12; and a non anodized portion 10 are obtained. The anodized precipitous particles 15 which had been present within the Al matrix prior to the anodic oxidation become oxide particles 15a, which are anodized along with the Al matrix (refer to FIG. 3B). In the case that only the anodized particles 15a are present as illustrated in FIG. 3B, no conductive substances are present within the porous layer 14p or the barrier layer 14b of the anodized film 11 in the obtained substrate 2 having an insulating layer (AAO substrate ). Even assuming a case in which anodized particles 15 are present at the interface between the porous layer 14p and the barrier layer 14b of the oxidized film 11, anodic oxidation is generated by the same electrochemical mechanism as that for the Al matrix. Therefore, it can be considered that a barrier layer 15b is present at the interfaces between anodized portions 15a′ and the non anodized portions 15′ of the anodized particles 15. Accordingly, regardless of the positions at which the anodized particles 15 are present, there is very little influence on the insulation properties of the AAO substrate. Note that as will be described later with reference to Embodiment 2 illustrated in FIG. 8, the anodized particles 15a and the sides thereof toward the barrier layer 14b differ form portions at which the anodized particles 15 are not present in that the porous structure is irregular. However, in order to simplify the description, the irregular porous structures are not illustrated in FIG. 3B.

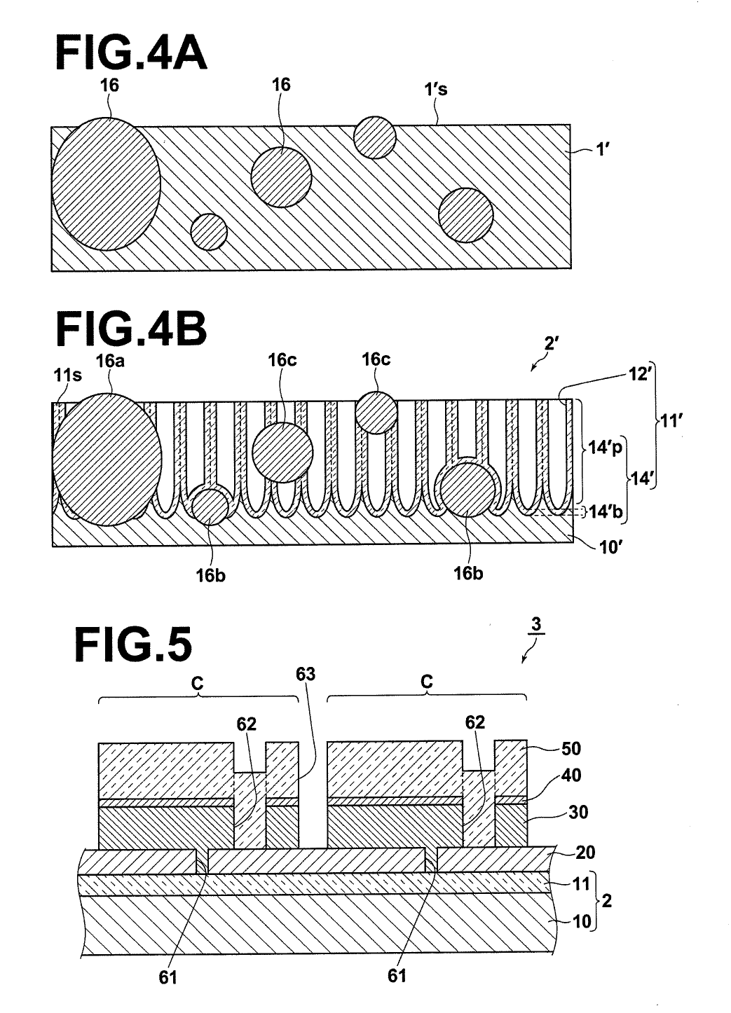

On the other hand, when an Al base material 1′ illustrated in FIG. 4A is anodized from the surface 1's thereof, an anodized film 11′ constituted by an anodized porous layer 14′p, a barrier layer 14′b, and fine pores 12′; and a non anodized portion 10′ are obtained. Non anodized precipitous particles 16 which had been present within the Al matrix prior to the anodic oxidation are not anodized, and are present as metal particles 16 (16a, 16b, and 16c) (refer to FIG. 4B). In the case that the non anodized precipitous particles 16 are not anodized and remain as the metal particles 16 as illustrated in FIG. 4B, the metal particles 16 influence the insulation properties of an obtained substrate 2′ having an insulating layer (AAO substrate 2′), regardless of whether they are present within the porous layer 14′p or the barrier layer 14′b. Particularly in the case of the metal particle 16a, the conductive particle is present throughout the entire thickness of the anodized film 11′. Therefore, no insulation properties are obtained, and this portion is in a conductive state. In the case of the metal particles 16b, although barrier layers are present on the surfaces thereof, there are many faults in the barrier layers, and the barrier layers exhibit poor insulation properties. In the case of the metal particles 16c, adverse influence is estimated to be slight. However, if micro shorts occur between the metal particles 16c and the barrier layers 14′ at the interfaces with the Al base material 1′, leakage current will be greater at these locations compared to that at portions at which the metal particles 16c are not present. Note that as will be described later with reference to FIG. 8, the sides of the non anodized particles 16c toward the barrier layer 14′b differ from portions at which the non anodized particles 16c are not present in that the porous structure is irregular. However, in order to simplify the description, the irregular porous structures are not illustrated in FIG. 4B.

As described above, there are differences in the amount of influence exerted by the non anodized precipitous particles 16 on the insulation properties of the AAO substrate 2′, according to the locations thereof. However, unavoidable impurities are randomly present within the entirety of industrial Al base materials. Therefore, a production method that performs anodic oxidation up to a point at which non anodized precipitous particles 16 are not present within a barrier layer is not realistic. Accordingly, it is necessary for the Al base material 1 to only include anodized precipitous particles 15, and to be substantially free of non anodized precipitous particles 16.

The substances which are anodized during anodic oxidation of the Al base material differ also according to the electrolysis solution which is employed. Examples of such substances for representative electrolysis solutions are listed in “Research Report on the Influence of Intermetallic Compounds on Surface Processability of Aluminum Alloys (Part 1)”, Surface Processing Technical Research Group, Research Committee, The Japan Institute of Light Metals, Ed., Jul. 20, 1990. For example, an intermetallic compound that includes Al or Mg is preferable as the anodized precipitous particle 15, due to the fact that such an intermetallic compound is anodized during anodic oxidation of Al base materials employing common electrolysis solutions. In addition, it is known that metallic Si is not anodized by anodic oxidation employing water soluble electrolysis solutions.

The Al base material may be obtained by employing pure industrial Al of the 1000 ordinal system as defined by JIS (Japanese Industrial Standards), or by employing an Al-Mg alloy of the 5000 ordinal system, and aluminidizing (forming intermetallic compounds with Al) Si, Fe, and the like, which are unavoidable impurities, or forming intermetallic compounds with Mg and the unavoidable impurities. For example, in the case that the industrial Al has the aforementioned composition, heat treatment after rolling may be performed at a temperature of 577° C. or less, which is the co-crystallization temperature of Si—Al, to prevent precipitation of metallic Si, to cause α-AlFeSi, which can be anodized, to be precipitated.

Metals in the JIS 1000 and the 5000 ordinal system were listed as examples of industrial Al. However, any desired Al base material may be employed, as long as precipitates thereof can be simultaneously anodized with the Al matrix. What is important is not the composition of the Al base material or alloy concentrations, but the electrochemical properties of the precipitate particles. In addition, various metal elements, such as Fe, Si, Mn, Cu, Mg, Cr, Zn, Bi, Ni, and Li may be included in highly pure Al. However, in the case that such metal elements are included in amounts that exceed the solid solute limit, it is important that they precipitate as aluminides (intermetallic compounds with Al).

It is necessary to remove metallic Si from the Al material particularly in the case that Si is not aluminidized, because metallic Si cannot be anodized. Known methods for removing metallic Si from Al other than that described above, in which the precipitation of metallic Si is prevented by performing the heat treatment after rolling at a temperature less than or equal to 577° C. (the co-crystallization temperature of Si−Al) and the Si is precipitated as anodizable α-AlFeSi, are listed below.

Japanese Patent Publication No. 62 (1987)-010315 discloses a method for refining aluminum that includes impurities by electrolysis. This method may be applied to remove metallic Si and other impurities. However, impurities are only removed from the surface of the aluminum, and metallic Si which his present within the aluminum at positions several μm or greater from the surface thereof cannot be removed. Therefore, this method is not suited in the case that an anodized film having a thickness of approximately 10 μm is to be formed.

Japanese Patent Publication No. 1 (1989)-279712 discloses a method that utilizes the phenomenon that when melted Al or Al alloys solidify, portions having high Al purity solidify first. In this method, molten metallic Si is condensed and removed from the non solidified molten metal during the final stages of solidification. Particularly in the case that the Al alloy includes Mg, the metallic Si becomes an Mg—Si intermetallic compound, and therefore the metallic Si can be reduced, along with Fe and Cu. However, this method has the drawbacks that it is not suited for large scale processing, and that a great amount of Al loss occurs.

In the case of industrial large scale production, the most superior method for removing metallic Si is the aforementioned method, in which heat treatment after rolling is performed at a temperature less than or equal to 577° C., which is the co-crystallization temperature of Si—Al. Specifically, ingots are obtained by performing solution heat treatment of aluminum and filtering. Then, isothermal heating is performed at approximately 550° C., rolling is performed when the temperature decreases to approximately 400° C., heat treatment is administered, and cold rolling is performed. Here, if the temperature of the heat treatment is low, formation of a-AlFeSi is not possible, and if the temperature is 577° C. or greater, separation occurs, resulting in metallic Si. Therefore, it is preferable for the heat treatment temperature to be within a range from 500° C. to 570° C., and more preferably to be within a range from 520° C. to 560° C. By removing metallic Si from the Al material in this manner, and performing anodic oxidation on the Al base material that only includes precipitous particles which are capable of being anodized, insulation failure initiation points can be eliminated, and thereby, insulation properties can be improved.

That metallic Si precipitate particles are not included is judged by confirming that Si peaks do not appear as greater than noise levels during X ray diffraction measurement of the surface of the Al base material, and by observing the surface or a cross section of the Al base material with a surface analyzing apparatus, which is a combination of an SEM (Scanning Electron Microscope) and an EPMA (Electron Probe Micro Analyzer). In the case that a precipitous particle is observed in an SEM image, and characteristic X rays for only Si or for only Si and Al are detected from the portion of the precipitous particle, it can be judged that the precipitous particle is metallic Si. The reason why it can be judged that the precipitous particle is metallic Si when only Si and Al are detected is because there is no compound constituted only by Si and Al. The characteristic X rays for Al which are detected in this case are characteristic X rays of the Al base material, due to the fact that the size of the precipitous particle is smaller than or equal to the spatial resolution capable of being detected by the EPMA.

In the case that polishing agents that include Si such as SiO₂ and SiC are utilized in the anodic oxidation process to adjust the surface of a sample to be observed, the polishing agents may become embedded into the soft crystal structures of Al. There is a possibility that such embedded polishing agents will be erroneously detected as precipitous particles. For example, there is a possibility that the polishing agent will be judged to be metallic Si, in the case that the X ray detecting method of the EPMA is EDS (Energy Dispersion System), which is not capable of detecting oxygen or carbon. Accordingly, when Al substrates which are polished in this manner are analyzed by EDS, the Al substrates may be immersed in an NaOH solution to dissolve the surface of the Al, cleansed, and then observed. By dissolving the surface of the Al, the embedded polishing agents are separated and removed. As described in the aforementioned document (edited by the Japan Institute of Light Metals), it is known that metallic Si does not dissolve in NaOH solutions. In addition, in the case that the surface of the Al is dissolved as described above, metallic Si particles will appear to protrude from the surface of the Al base material. Therefore, an advantageous effect, that the metallic Si particles can be more clearly identified during observation of an SEM image, is obtained.

Note that methods other than X ray diffraction measurement and surface analysis of the Al base material may be employed to perform the judgment regarding whether metallic Si particles are included. A method in which the Al base material is dissolved in an NaOH solution, then undissolved precipitates (smut) are collected and analyzed chemically or by X ray diffraction is an example of such a method. However, as described previously, the definition of the phrase “metallic Si particles are not included” refers to a degree of exclusivity up to an amount of metallic Si that can be observed by X ray diffraction measurement and observation by an EPMA of the Al base material. Note that the allowable range of metallic Si particles that corresponds to the aforementioned “range that practically enables the objective of the present invention to be met” is equivalent to a range in which metallic Si cannot be observed by X ray diffraction measurement and observation by an EPMA of the Al base material, in view of the definition of “not included”.

As described above, the Al base material 1 of the first embodiment is characterized by including only the precipitate particles 15, which are of a substance which is capable of being anodized by anodic oxidation, as precipitate particles.

The AAO substrate 2 (metal substrate having an insulating layer) which is produced using the Al base material 1 is capable of realizing high voltage resistance and low leakage current in the insulating layer without any additional processing, because the Al base material does not include precipitate particles of substances which are not anodized. Accordingly, the first embodiment enables obtainment of a metal substrate having an insulating layer which is capable of being produced by a simple process, has heat resistance during semiconductor processing, is superior in voltage resistance, and has small leakage current.

The thickness of the Al base material 1 may be selected as appropriate within a range from 50 μm to 5000 μm for use as the metal substrate having an insulating layer 2. Note that when producing the metal substrate having an insulating layer 2, the thickness of the Al base material 1 decreases due to anodic oxidation, and cleansing and polishing prior to the anodic oxidation. Therefore, it is necessary to take the amount of decrease in thickness into consideration when selecting the thickness of the Al base material 1.

Anodic oxidation may be executed by immersing the Al base material 1, which functions as an anode, and a cathode in an electrolysis solution, and the applying voltage between the anode and the cathode. In addition, a cleansing process and a polishing/smoothing process are administered on the surface of the Al base material 1 as necessary prior to the anodic oxidation. Carbon, Al or the like may be utilized as the cathode. The electrolyte is not particularly limited, and preferable examples are acidic electrolysis solutions that include one or more acids selected from: sulfuric acid; phosphoric acid; chromic acid; oxalic acid; sulfamic acid; benzenesulfonic acid; amidosulfonic acid; and the like. The conditions for anodic oxidation depend on the electrolytes which are employed, and are not particularly limited. The conditions may be set such that: the electrolyte concentration is within a range from 1 weight % to 80 weight %; the solution temperature is within a range from 5° C. to 70° C.; the current density is within a range from 0.005 A/cm² to 0.60 A/cm²; the voltage is within a range from 1V to 200V; and the electrolysis time is within a range from 3 minutes to 500 minutes. It is preferable for the electrolyte to be sulfuric acid, phosphoric acid, oxalic acid, or a mixture thereof. In the case that these acids are employed as the electrolytes, it is preferable for the electrolyte concentration to be within a range from 4 weight % to 30 weight %, the solution temperature to be within a range from 10° C. to 30° C., the current density to be within a range from 0.002 A/cm² to 0.30 A/cm², and the voltage to be within a range from 20V to 100V.

When the Al base material 1 is anodized, oxidizing reactions progress from the surface is in a substantially perpendicular direction, to form the anodized film 11 and the non anodized portion 10. In the case that the aforementioned acidic electrolysis solution is employed, the anodized film 11 a great number of fine columnar structures 14 which are hexagonal in plan view are arranged without gaps therebetween in the anodized film 11, a fine pore 12 is formed in the centers of each of the fine columnar structures 14, and the bottom surfaces of the fine pores 12 are of a rounded shape. The barrier layer 14b (generally of a thickness within a range from 0.02 μm to 0.1 μm) is formed at the bottoms of the fine columnar structures 14. Note that a dense anodized film may be obtained instead of the anodized film having the porous fine columnar structures 14 arranged therein, by administering the electrolysis process using a neutral electrolysis solution such as boric acid instead of the acidic electrolysis solution. In addition, a pore filling method, in which an electrolysis process is performed with a neutral electrolysis solution after forming the porous anodized film 11 with an acidic electrolysis solution, or the like may be utilized in order to increase the thickness of the barrier layer 14b (refer to H. Takahashi and S. Nagayama, “Pore-Filling of Porous Anodic Oxide Films on Aluminium”, Journal of the Metal Finishing Society of Japan, Vol. 27, pp. 338-343, 1976).

The thickness of the anodized film 11 is not particularly limited, and it is necessary only to be of a thickness that secures insulation properties and a surface hardness capable of preventing damage due to mechanical shock during handling. However, there are cases that problems with respect to flexibility will occur if the thickness is too great. For these reasons, the preferred thickness is within a range from 0.5 μm to 50 μm. The thickness of the anodized film 11 can be controlled by galvanostatic electrolysis, potentiostatic electrolysis, and electrolysis time. Note that the thickness of the Al base material 1 decreases due to anodic oxidation, and cleansing and polishing prior to the anodic oxidation. Therefore, it is necessary to take the amount of decrease in thickness into consideration when selecting the thickness of the Al base material 1.

The AAO substrate 2 (metal substrate having an insulating layer) has favorable adhesive properties between the metal layer (non anodized portion 10) and the insulating layer (anodized film 11). Therefore, it is only necessary for the anodized film 11 to be formed as an insulating layer on one surface of the Al base material 1, as illustrated in FIG. 3B. However, in the case that problems occur during manufacturing steps for a semiconductor element due to a difference in the coefficients of thermal expansion of the non anodized portion 10 and the anodized film 11, the anodized film 11 may be formed as an insulating layer on both surfaces of the Al base material 1. As methods for anodizing both surfaces of the Al base material 1, there is a method in which insulating material is coated on both surfaces, which are then anodized one at a time, and a method in which both surfaces are anodized simultaneously.

### [Semiconductor Element]

The structure of a semiconductor element according to a second embodiment of the present invention will be described with reference to the drawings. Here, the semiconductor element of the second embodiment is a photoelectric converting element, in which the semiconductor is a photoelectric converting semiconductor. FIG. 5 is a schematic sectional diagram that illustrates the photoelectric converting element 3 according to the second embodiment of the present invention.

The photoelectric converting element 3 is an element, formed by laminating a lower electrode 20 (underside electrode), a photoelectric converting semiconductor 30, a buffer layer 40, and an upper electrode 50 (transparent electrode) on the AAO substrate (metal substrate having an insulating layer) of the first embodiment. The lower electrode, the photoelectric converting layer, and the upper electrode of photoelectric converting elements C are formed on the anodized film, which functions as an insulating layer. Hereinafter, the photoelectric converting semiconductor will be referred to as “photoelectric converting layer”.

First groves 61 that penetrate through only the lower electrode 20, second grooves that penetrate through the photoelectric converting layer 30 and the buffer layer 40, and third grooves 63 that penetrate through the photoelectric converting layer 30, the buffer layer 40, and the upper electrode 50 are formed in the photoelectric converting element 3.

In the structure described above, a configuration in which the first through third grooves 61 through 63 separate the element into a great number of the elements C is obtained. In addition, the upper electrode 50 fills the second grooves 62, resulting in a structure in which the upper electrode 50 of a given element C is connected in series to the lower electrode 20 of an adjacent element C.

### (Photoelectric Converting Layer)

The photoelectric converting layer 30 is a layer that generates current by absorbing light. Although the main component of the photoelectric converting layer 30 is not particularly limited, it is preferable for the main component of the photoelectric converting layer 30 to be a compound semiconductor having at least one type of chalcopyrite structure. It is also preferable for the main component of the semiconductor to be at least one type of compound semiconductor comprising Ib group elements, IIIb group elements, and VIb group elements.

Further, it is preferable for the main component of the semiconductor being at least one type of compound semiconductor, to comprise: at least one Ib group element selected from a group consisting of Cu and Ag; at least one IIIb group element selected from a group consisting of Al, Ga, and In; and at least one VIb group element selected from a group consisting of S, Se, and Te, because these elements have high light absorption rates and exhibit high photoelectric conversion efficiency.

Examples of the aforementioned compound semiconductors include: CuAlS₂; CuGaS₂; CuInS₂; CuAlSe₂; CuGaSe₂; CuInSe₂ (CIS); AgAlS₂; AgGaS₂; AgInS₂; AgAlSe₂; AgGaSe₂; AgInSe₂; AgAlTe₂; AgGaTe₂; AgInTe₂; Cu(In₁₋ₓGaₓ)Se₂ (CIGS); Cu(In₁₋ₓAlₓ)Se₂; Cu(In₁₋ₓGaₓ) (S,Se)₂; Ag(In₁₋ₓGaₓ)Se₂; and Ag(In₁₋ₓGaₓ) (S,Se)₂.

It is particularly preferable for the photoelectric converting layer 30 to include CuInSe₂ (CIS) and/or Cu(In₁₋ₓGaₓ)Se₂ (CIGS), which is CuInSe₂ (CIS) in which Ga is present as a solid solute. CIS and CIGS are semiconductors having chalcopyrite crystal structures, and are reported to exhibit high light absorption rates and high photoelectric conversion efficiency. In addition, deterioration of efficiency due to irradiation of light is slight, and they are superior in durability.

The photoelectric converting layer 30 includes impurities in order to obtain a desired semiconductor conductivity. The impurities may be included in the photoelectric converting layer 30 by diffusion from adjacent layers and/or by aggressive doping. In the photoelectric converting layer 30, the constituent elements and/or the impurities within the I-III-VI group semiconductor may have a concentration distribution, and a plurality of layer regions having different semiconductor properties, such as the n type, the p type, and the i type may be included. For example, in CIGS systems, the widths of band gaps and carrier motility can be controlled by the amount of Ga having a distribution in the thickness direction, and the photoelectric conversion efficiency can be finely designed. The photoelectric converting layer 30 may include one or more other types of semiconductors other than those of the I-III-VI groups. Examples of semiconductors other than those of the I-III-VI groups include: semiconductors of IVb group elements, such as Si (IV group semiconductors); semiconductors of IIIb group elements and Vb group elements, such as GaAs (III-V group semiconductors); and semiconductors of IIb group elements and VIb group elements, such as CdTe (II-VI group semiconductors). Components other than the impurities provided to obtain desired semiconductor conductivity may be included in the photoelectric converting layer 30, as long as no adverse effects are imparted on the semiconductor properties thereof. Although the amount of the group semiconductors which are included in the photoelectric converting layer 30 is not particularly limited, 75 weight % or greater is preferable, 95 weight % or greater is more preferable, and 99 weight % or greater is most preferable.

Known methods for forming the CIGS layer include: 1) the multiple source simultaneous vapor deposition method (refer to J. R. Tuttle et al., “The Performance of Cu (In, Ga) Se₂-Based Solar Cells in Conventional and Concentrator Applications”, Mat. Res. Soc. Symp. Proc. Vol. 426, pp. 143-151, 1996; and H. Miyazaki et al., “Growth of high-quality CuGaSe₂ thin films using ionized Ga precursor”, phys. Stat. sol. (a), Vol. 203, pp. 2603-2608, 2006); the selenization method (refer to. Nakada et al., “CuInSe₂-based solar cells by Se-vapor selenization from Se-containing precursors”, Solar Energy Materials and Solar Cells, Vol. 35, pp. 209-214, 1994; and T. Nakada et al., “THIN FILMS OF CuInSe₂ PRODUCED BY THERMAL ANNEALING OF MULTILAYERS WITH ULTRA-THIN STACKED ELEMENTAL LAYERS”, Proceedings of the 10th European Photovoltaic Solar Energy Conference (EU PVSEC), pp. 887-890, 1991); 3) the sputtering method (J. H. Ermer et al., “CdS/CuInSe₂ JUNCTIONS FABRICATED BY DC MAGNETRON SPUTTERING OF Cu₂Se AND In₂Se₃”, Proceedings of the 18th IEEE Photovoltaic Specialists Conference, pp. 1655-1658, 1985; and T. Nakada et al., “Polycrystalline CuInSe₂ Thin Films for Solar Cells by Three-Source Magnetron Sputtering”, Japanese Journal of Applied Physics, Vol. 32, Part 2, No. 8B, pp. L1169-L1172, 1993); 4) the hybrid sputtering method (T. Nakada et al., “Microstructural Characterization for Sputter-Deposited CuInSe₂ Films and Photovoltaic Devices”, Japanese Journal of Applied Physics, Vol. 34, Part 1, No. 9A, pp. 4715-4721, 1995); and 5) the mechanochemical processing method (T. Wada et al., “Fabrication of Cu(In,Ga)Se₂ thin films by a combination of mechanochemical and screen-printing/sintering processes”, Physica status solidi (a), Vol. 203, No. 11, pp. 2593-2597, 2006). Other methods for forming the CIGS layer include the screen printing method, the close space sublimation method; the MOCVD method, and the spray method. For example, fine particle films that include Ib group elements, IIIb group elements, and VIb group elements may be formed on the substrate by the screen printing method or the spray method, then pyrolytic decomposition may be performed (at this time, the pyrolytic decomposition process may be performed within a VIb group element atmosphere), to obtain crystals of a desired composition (refer to Japanese Unexamined Patent Publication Nos. 9 (1997)-074065, 9(1997)-074213 and the like).

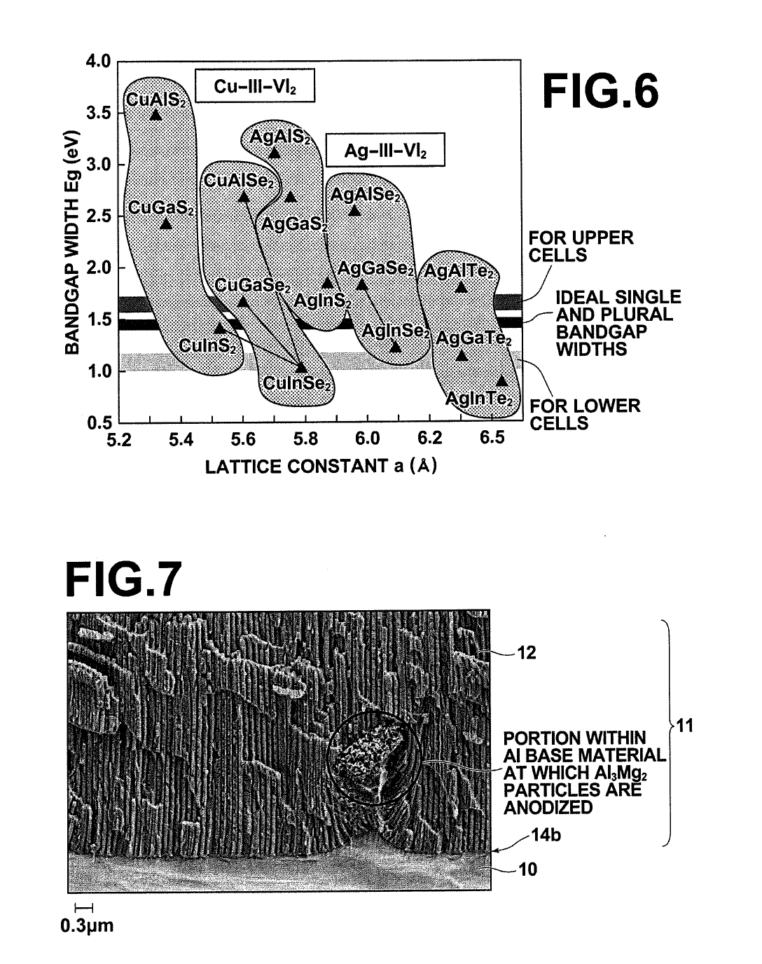

FIG. 6 is a graph that illustrates the relationships among the lattice constants of I-III-VI compound semiconductors and bandgaps. Various bandgaps can be obtained, by varying the compositional ratios. If photons having energy greater than the bandgap enter the semiconductors, the energy that exceeds the bandgap becomes heat loss. It is known that the conversion efficiency becomes maximal within a range from 1.4 eV to 1.5 eV from theoretical calculations performed with respect to combinations of the spectrum of sunlight and bandgaps. Bandgaps having high conversion efficiencies can be obtained by increasing the bandgaps in order to improve the photoelectric conversion efficiency. The bandgaps can be increased, by increasing the Ga concentration of Cu (In, Ga) Se₂ (CIGS), by increasing the Al concentration of Cu (In, Al), and by increasing the S concentration of Cu (In, Ga) (S, Se)₂, for example. In the case of CIGS, the bandgap can be adjusted within a range from 1.04 eV to 1.68 eV.

### (Electrodes and Buffer Layer)

The lower electrode 20 (underside electrode) and the upper electrode 50 (transparent electrode) are both made from conductive materials. It is necessary for the upper electrode 50 on the light incident side, to be transmissive with respect to light.

Mo may be employed as the material of the lower electrode 20, for example. It is preferable for the thickness of the lower electrode 20 to be greater than or equal to 100 nm, and more preferably to be within a range from 0.45 μm to 1.0 μm. The method for forming the lower electrode 20 is not particularly limited. Examples for forming the lower electrode 20 include vapor phase film forming methods, such as electron beam vapor deposition and sputtering. It is preferable for ZnO, ITO (Indium Tin Oxide), SnO₂, or combinations thereof to be the main component of the upper electrode 50. The upper electrode 50 may be of a single layer structure, or may be of a laminated two layered structure. It is preferable for CdS, ZnS, ZnO, ZnMgO, ZnS (O, OH), or combinations thereof to be the material of the buffer layer 40.

A semiconductor element having an Mo lower electrode, a CIGS photoelectric converting layer, a CdS buffer layer, and a ZnO upper electrode is an example of a preferred combination of compositions.

It is reported that alkali metal elements (Na elements) within soda lime glass substrates disperse into CIGS films and improve the photoelectric conversion efficiency of photoelectric converting elements that employ soda lime glass substrates. In the present embodiment as well, it is preferable to disperse alkali metals within the CIGS film. Examples of methods for dispersing alkali metal elements within the CIGS film include: a method in which a layer that includes alkali metal elements is formed on the No lower electrode by the vapor deposition method or the sputtering method (refer to Japanese Unexamined Patent Publication No. 8 (1996)-222750, for example); a method in which an alkali layer constituted by Na₂S or the like is formed on the Mo lower electrode by the immersion method (refer to International Patent Publication No. WO03/069684, for example); and a method in which a precursor including In, Cu, and Ga metal elements is formed on the Mo lower electrode, then causing a solution containing sodium molybdate, for example, to adhere to the precursor.

Another favorable configuration is that in which a layer that includes one or more types of alkali metal compounds, such as Na₂S, Na₂Se, NaCl, NaF, and sodium molybdate salt, is provided within the lower electrode 20.

The conductivity types of the photoelectric converting layer 30 through the upper electrode 50 are not particularly limited. Generally, the photoelectric converting layer 30 is a p layer, the buffer layer 40 is an n layer (such as n-CdS), and the upper electrode 50 is an n layer (such as n-ZnO) or of a laminated structure including an i layer and an n layer (such as a laminated structure constituted by an i-ZnO layer and an n-ZnO layer). In these conductivity types, it is considered that a p-n junction or a p-I-n junction is formed between the photoelectric converting layer 30 and the upper electrode 50. In addition, in the case that the buffer layer 40 formed by CdS is provided on the photoelectric converting layer 30, Cd becomes dispersed, an n layer is formed on the surface of the photoelectric converting layer 30, and it is considered that a p-n junction is formed within the photoelectric converting layer. It is also considered that an i layer may be provided as a backing layer to the n layer within the photoelectric converting layer 30, to form a p-I-n junction within the photoelectric converting layer.

### (Other Layers)

The photoelectric converting element 3 may be equipped with layers other than those described, as necessary. For example, adhesion layers (buffer layers) for improving the adhesion among layers may be provided between the metal substrate having the insulating layer 2 and the lower electrode 20 and/or between the lower electrode 20 and the photoelectric converting layer 30. In addition, an alkali barrier layer, for suppressing dispersion of alkali ions, may be provided between the metal substrate having the insulating layer 2 and the lower electrode 20. Please refer to Japanese Unexamined Patent Publication No. 8 (1996)-222750 regarding the alkali barrier layer.

The photoelectric converting element 3 may be favorably utilized in solar batteries and the like. A solar battery may be constituted by adhesively attaching a glass cover, a protective film or the like onto the photoelectric converting element 3. However, the semiconductor element of the present invention is not limited to photoelectric converting elements. The present invention may be applied to mesa type semiconductor elements, in addition to the planar type semiconductor element described as the embodiment above. In addition, the present invention may also be applied to vertical type semiconductor elements and horizontal type semiconductor elements. As specific examples, the present invention may be applied to flexible transistors and the like.

As described above, the semiconductor element 3 and the solar battery of the present invention employ the metal substrate with an insulating layer 2 of the present invention. Therefore, the same advantageous effects as those exhibited by the metal substrate with an insulating layer 2 are exhibited, and the semiconductor element is that which can maximally utilize the inherent photoelectric converting properties thereof, and also is superior in durability.

### Embodiments

Hereinafter, embodiments of the semiconductor element of the present invention and comparative examples will be described.

### (Evaluation Criteria)

### <Identification of Intermetallic Compounds 1-X Ray Diffraction>

Identification of intermetallic compounds was performed by RINT-2000, an X ray diffraction apparatus by Rigaku, using CuKα beams (50 kV, 200 mA) to perform measurements. Higher peak intensities indicate greater masses of precipitous matter. The conditions and properties of the embodiments and the comparative example are indicated in Table 1. In Table 1, “-” indicates that no particular diffraction peak was detected, and that only noise level intensities were detected. Cps (counts per second) were employed as the units of measurement, and intensities of approximately 150 cps or less were designated as noise level intensities.

### <Identification of Intermetallic Compounds 2-SEM and EPMA>

Identification of intermetallic compounds was also performed by a surface analyzing apparatus, in which an SEM (Ultra 55 by Zeiss) and an EPMA (NORAN System (Energy Dispersion Type) by Thermo) are combined. The acceleration voltage was 10 kV, and the spatial resolution is approximately 0.5 μm. Weight % were used as the units of measurement. In Table 1, “-” indicates that no intermetallic compounds were detected.

### Embodiment 1

A solution was prepared employing aluminum having a purity of 99.99% or greater, such as that employed in JIS1N99, and solution heat treatment and filtration were performed, to produce an ingot having a thickness of 500 mm and a width of 1200 mm by the DC casting method. The surface of the ingot was milled for an average thickness of 10 mm by a surface miller. Then, isothermal heating was performed for approximately five hours at 550° C. When the temperature decreased to 400° C., the ingot was rolled by a hot rolling mill to form a rolled plate having a thickness of 2.7 mm. Further, the heat treatment was performed at 500° C. for one hour by an annealing device, and the rolled plate was finished to have a thickness of 0.24 mm by cold rolling employing a mirror finished roll.

The surface of this Al material was ultrasonically cleansed with ethanol, then electrolytically polished with a mixed solution of acetic acid and perchloric acid. Then, potentiostatic electrolysis at 40V was administered the Al plate within a 0.5 mol/L oxalic acid solution, to form an anodized film having a thickness of 10 μm on the surface of the Al plate. No precipitous matter was found within the Al base material, and no disruptions were present in the porous structure of the anodized film.

### Embodiment 2

A solution was prepared employing aluminum having a purity of 99.99% or greater, such as that employed in JIS1N99, and Mg at 4 weight %. Other than the addition of the Mg, an Al material was produced in the same mariner as that of Embodiment 1.

When X ray diffraction measurement was administered on this Al material, a peak appeared at 37.5°, and it was confirmed that the Al material included Al₃Mg₂. It was confirmed that fine precipitous matter smaller than 1 μm in size was present in the Al base material, which was identified as Al₃Mg₂ by EPMA as well.

Next, an anodized film having a thickness of 10 μm in the same manner as that of Embodiment 1.

As illustrated in FIG. 7, there are disrupted portions in the porous structure of the anodized film. Mg was detected along with Al and oxygen from these portions by EPMA measurement. Accordingly, it was judged that these portions are locations at which Al₃Mg₂ was anodized. However, the portions at which Al₃Mg₂ was present were not empty spaces, but rather disrupted porous structures, and the disrupted porous structures were continuous to the Al base material.

### Embodiment 3

A solution was prepared employing aluminum having a purity of 99.99% or greater, such as that employed in JIS1N99, and solution heat treatment and filtration were performed, to produce an ingot having a thickness of 500 mm and a width of 1200 mm by the DC casting method. Then, an aluminum material having a thickness of 0.24 mm was produced in the same manner as that of Embodiment 1, except that the heat treatment was performed at a temperature of 520° C.

When X ray diffraction measurement was administered on this Al material, a peak appeared at 42.0°, and it was confirmed that the Al material included α-AlFeSi. It was confirmed that fine precipitous matter having a maximum size of 3 μm in size was present in the Al base material, which was identified as Al₃Fe, Al₆Fe, and AlFeSi by EPMA.

Next, an anodized film having a thickness of 10 μm in the same manner as that of Embodiment 1. As a result of EPMA measurement which was administered on the cross section of the anodized film, Al₃Fe, Al₆Fe, and AlFeSi were detected along with oxygen. Accordingly, it was judged that these portions are locations at which Al₃Fe, Al₆Fe, and α-AlFeSi were anodized.

### Embodiment 4

A solution was prepared employing aluminum having a purity of 99.0% or greater, such as that employed in JIS1000, and solution heat treatment and filtration were performed, to produce an ingot having a thickness of 500 mm and a width of 1200 mm by the DC casting method. Then, an aluminum material having a thickness of 0.24 mm was produced in the same manner as that of Embodiment 1, except that the heat treatment was performed at a temperature of 520° C.

When X ray diffraction measurement was administered on this Al material, peaks appeared at 24.1°, 18.0°, and 42.0°, and it was confirmed that the Al material included Al₃Fe, Al₆Fe, and α-AlFeSi. It was confirmed that fine precipitous matter having a maximum size of 3 μm in size was present in the Al base material, which was identified as Al₃Fe, Al₆Fe, and AlFeSi by EPMA.

Next, an anodized film having a thickness of 10 μm in the same manner as that of Embodiment 1. As a result of EPMA measurement which was administered on the cross section of the anodized film, Al₃Fe, Al₆Fe, and AlFeSi were detected along with oxygen. Accordingly, it was judged that these portions are locations at which Al₃Fe, Al₆Fe, and α-AlFeSi were anodized.

### Embodiment 5

An Al material was produced in the same manner as that of Embodiment 4, except that heat treatment was performed for one hour at 560° C. by an annealing device.

When X ray diffraction measurement was administered on this Al material, peaks appeared at 24.1°, 18.0°, and 42.0°, and it was confirmed that the Al material included Al₃Fe, Al₆Fe, and α-AlFeSi. It was confirmed that fine precipitous matter having a maximum size of 3 μm in size was present in the Al base material, which was identified as Al₃Fe, Al₆Fe, and AlFeSi by EPMA. Next, an anodized film having a thickness of 10 μm in the same manner as that of Embodiment 1. As a result of EPMA measurement which was administered on the cross section of the anodized film, Al₃Fe, Al₆Fe, and AlFeSi were detected along with oxygen. Accordingly, it was judged that these portions are locations at which Al₃Fe, Al₆Fe, and α-AlFeSi were anodized.

### Embodiment 6

An Al material was produced in the same manner as that of Embodiment 4, except that a solution was prepared employing aluminum having a purity of 99.0% or greater, such as that employed in JIS1000, to which Fe was added at 1 weight %.

When X ray diffraction measurement was administered on this Al material, peaks appeared at 24.1°, 18.0°, and 42.0°, and it was confirmed that the Al material included Al₃Fe, Al₆Fe, and α-AlFeSi. It was confirmed that fine precipitous matter having a maximum size of 3 μm in size was present in the Al base material, which was identified as Al₃Fe, Al₆Fe, and AlFeSi by EPMA.

Next, an anodized film having a thickness of 10 μm in the same manner as that of Embodiment 1. As a result of EPMA measurement which was administered on the cross section of the anodized film, Al₃Fe, Al₆Fe, and AlFeSi were detected along with oxygen. Accordingly, it was judged that these portions are locations at which Al₃Fe, Al₆Fe, and α-AlFeSi were anodized.

### Embodiment 7

An Al material was produced in the same manner as that of Embodiment 6. The surface of the Al material was ultrasonically cleansed, and electrolytically polished with a mixed solution of acetic acid and perchloric acid. Then, potentiostatic electrolysis at 13V was administered the At plate within a 1.73 mol/L sulfuric acid solution, to form an anodized film having a thickness of 10 μm on the surface of the Al plate. As a result of EPMA measurement which was administered on the cross section of the anodized film, Al₃Fe, Al₆Fe, and AlFeSi were detected along with oxygen. Accordingly, it was judged that these portions are locations at which Al₃Fe, Al₆Fe, and α-AlFeSi were anodized.

### COMPARATIVE EXAMPLE 1

A solution was prepared employing aluminum having a purity of 99.8% or greater, such as that employed in JIS1080, and solution heat treatment and filtration were performed, to produce an ingot having a thickness of 500 mm and a width of 1200 mm by the DC casting method. An Al material having a thickness of 0.24 mm was produced in the same manner as that of Embodiment 1, except that heat treatment was performed as a temperature of 400° C.

When X ray diffraction measurement was administered on this Al material, peaks appeared at 24.1° and 28.4°, and it was confirmed that the Al material included Al₃Fe and metallic Si. It was confirmed that fine precipitous matter having a maximum size of 3 μm in size was present in the Al base material, which was identified as Al₃Fe and Si by EPMA.

Next, an anodized film having a thickness of 10 μm in the same manner as that of Embodiment 1. As a result of EPMA measurement which was administered on the cross section of the anodized film, the Al₃Fe was anodized, but the metallic Si was not anodized, and remained in the Al material as metallic Si.

### COMPARATIVE EXAMPLE 2

An Al material was produced in the same manner as that of Comparative Example 1, except that a solution was prepared employing aluminum having a purity of 99.0% or greater, such as that employed in JIS1100.

When X ray diffraction measurement was administered on this Al material, peaks appeared at 24.1°, 18.0°, and 28.4°, and it was confirmed that the Al material included Al₃Fe, Al₆Fe, and metallic Si. It was confirmed that fine precipitous matter having a maximum size of 3 μm in size was present in the Al base material, which was identified as Al₃Fe, Al₆Fe, and metallic Si by EPMA.

Next, an anodized film having a thickness of 10 μm in the same manner as that of Embodiment 1. As a result of EPMA measurement which was administered on the cross section of the anodized film, the Al₃Fe and Al₆Fe were anodized, but the metallic Si was not anodized, and remained in the Al material as metallic Si.

### COMPARATIVE EXAMPLE 3

An Al material was produced in the same manner as that of Comparative Example 1, except that a solution was prepared employing aluminum having a purity of 99.0% or greater, such as that employed in JIS1100, and heat treatment was performed at a temperature of 600° C.

When X ray diffraction measurement was administered on this Al material, peaks appeared at 24.1°, 18.0°, 42.0°, and 28.4°, and it was confirmed that the Al material included Al₃Fe, Al₆Fe, α-AlFeSi, and metallic Si. It was confirmed that fine precipitous matter having a maximum size of 3 μm in size was present in the Al base material, which was identified as Al₃Fe, Al₆Fe, AlFeSi, and metallic Si by EPMA.

Next, an anodized film having a thickness of 10 μm in the same manner as that of Embodiment 1. As a result of EPMA measurement which was administered on the cross section of the anodized film, the Al₃Fe, Al₆Fe, and AlFeSi were anodized, but the metallic Si was not anodized, and remained in the Al material as metallic Si.

### COMPARATIVE EXAMPLE 4

An Al material was produced in the same manner as that of Comparative Example 2. Thereafter, an anodized film having a thickness of 10 μm was formed in the same manner as that of Embodiment 7. As a result of EPMA measurement which was administered on the cross section of the anodized film, Al₃Fe and Al₆Fe were anodized, but metallic Si was not anodized, and remained in the Al material as metallic Si.

### (Measurement of Insulation Properties)

The insulation failure voltage was measured for each of the substrates of the Embodiments and Comparative Examples, using the Al layer thereof as a positive pole. The measurement of insulation properties was performed by providing an electrode formed of Au having a thickness of 0.2 μm and a diameter of 3.5 mm by mask vapor deposition, applying constant voltage to the Au electrode, and by observing temporal changes in leakage current. The currents were measured for 60 seconds at 1 second intervals. Here, values obtained by dividing the leakage current by the area of the Au electrode (9.6 mm²) were designated as leakage current densities.

Note that the present inventor discovered that anodized films exhibit extremely high insulation properties in cases that voltages are applied to Al layers as positive poles, compared to cases in which voltages are applied to Al layers as negative poles (refer to Japanese Patent Application No. 2009-093536). The detailed reasons for this phenomenon are unclear at the present time, but it is estimated that barrier layers undergo film growth while faults therein are self repaired. That is, by applying voltages such that the Al base material 1 becomes a positive pole, electric fields become concentrated at portions within the barrier layers which are electrically fragile, and anodic oxidation phenomena are prioritized in the vicinities of these fragile portions. Thereby, self repair of the faults is prioritized, and it is estimated that fault free barrier layers are grown over time.

### (Evaluations)

FIG. 8A is a graph that illustrates the excess current properties of Embodiment 1. No great leakage current is recognized in the excess current properties of FIG. 8A, and insulation failure did not occur even when a voltage of 1000V was applied. The leak current density when a voltage of 200V was applied for 60 seconds was 1.0·10⁻⁷A/cm².

FIG. 8B is a graph that illustrates the excess current properties of Embodiment 2. Similarly to Embodiment 1, no great leakage current is recognized in the excess current properties of FIG. 8B, and insulation failure did not occur even when a voltage of 1000V was applied. The leak current density when a voltage of 200V was applied for 60 seconds was 7.5·10⁻⁸A/cm². In Embodiment 2, the only precipitous particles are aluminidized compounds of Mg. Accordingly, it was proven that an Al plate having only precipitous particles which are capable of being anodized of the present invention exhibits the same advantageous effects as a highly pure Al plate.

Similarly, insulation failure did not occur in any of Embodiments 3 through 7. The leakage current densities when a voltage of 200V was applied for 60 seconds of each of Embodiments 3 through 7 were: 2.2·10⁻⁸A/cm², 6.6·10⁻⁷A/cm², 7.2·10⁻⁷A/cm², 8.5·10⁻⁷A/cm², and 1.5·10⁻⁶A/cm², respectively.

FIG. 8C is a graph that illustrates the excess current properties of Comparative Example 1. Although no great fluctuations in leakage current were observed in the excess current properties of FIG. 8C, insulation failure occurred fifteen seconds after application of a voltage of 600V was initiated. The causes for the insulation failure are assumed to be: that the insulation properties are poor due to the great number of faults because of the presence of metallic Si (non anodized precipitous particles) within the barrier layer; and that metallic Si does not have self repairing Al elements, resulting in no growth of the barrier layer. As a result, the leakage current properties and the voltage resistance properties were very poor compared to those of the Embodiments, and sufficient insulation properties could not be obtained. The leak current density when a voltage of 200V was applied for 60 seconds was 5.1·10⁻⁶A/cm².

Similarly, insulation failure occurred in Comparative Examples 2 through 4 at 330V, 420V, and 360V, respectively. It is assumed that insulation failure occurred in Comparative Examples 2 through 4 at lower applied voltages than that of Comparative Example 1, due to the higher amounts of metallic Si content thereof. The leakage current densities when a voltage of 200V was applied for 60 seconds of each of Comparative Examples 2 through 4 were: 1.6·10⁻⁵A/cm², 9.6·10⁻⁶A/cm², and 3.3·10⁻⁵A/cm², respectively.

As described above, the Al materials of Embodiments 1 through 7 are substantially free of metallic Si. It was confirmed that insulation failure voltages are 1000V or greater, in cases that anodized films are formed employing such Al materials. In contrast, the Al materials of Comparative Examples 1 through 4 include metallic Si, although to different degrees. It was confirmed that the metallic Si is not anodized and remains in the Al materials as metallic Si, in cases that anodized films are formed employing such Al materials, and that insulation failures occur at applied voltages of less than 1000V. Accordingly, it can be assumed that the non anodized metallic Si particles are the insulation failure initiation points.

In addition, no problems were observed with respect to the insulation properties in cases that precipitous particles are present, but are precipitous particles which are capable are being anodized, in Embodiments 2 through 7. It is desirable for Al base materials to include only substances which are capable of being anodized, and to substantially not include metallic Si, which is not capable of being anodized.

The conditions and properties of the Embodiments and the Comparative Examples are illustrated in Table 1 below.

TABLE 1

| | | Heat | | | | | | | | XRD (cps) | | | | |
|---|---|---|---|---|---|---|---|---|---|---|---|---|---|---|
| | | Treatment | Composition (Weight %) | | | | | | | Al₃Fe | Al₆Fe | α-AlFeSi | Si | Al₃Mg₂ |
| | Purity | Conditions | Si | Fe | Cu | Mn | Mg | Zn | Ti | (24.1°) | (18.0°) | (42.0°) | (28.4°) | (37.5°) |
| Embodiment 1 | 99.99 | 500° C. | 0.002 | 0.005 | 0.002 | — | — | — | — | — | — | — | — | — |
| | | 1 hour | | | | | | | | | | | | |
| Embodiment 2 | 99.99 | 500° C. | 0.003 | 0.004 | 0.002 | — | 4.002 | — | — | — | — | — | — | 132.6 |
| | | 1 hour | | | | | | | | | | | | |
| Embodiment 3 | 99.8 | 520° C. | 0.082 | 0.091 | 0.008 | 0.002 | 0.004 | 0.006 | 0.001 | — | — | 389 | — | — |
| | | 1 hour | | | | | | | | | | | | |
| Embodiment 4 | 99.0 | 520° C. | 0.302 | 0.453 | 0.071 | 0.023 | 0.008 | 0.035 | 0.006 | 422 | 235 | 867 | — | — |
| | | 1 hour | | | | | | | | | | | | |
| Embodiment 5 | 99.0 | 560° C. | 0.308 | 0.458 | 0.072 | 0.023 | 0.009 | 0.033 | 0.005 | 487 | 296 | 682 | — | — |
| | | 1 hour | | | | | | | | | | | | |
| Embodiment 6 | 99.0 | 520° C. | 0.302 | 1.004 | 0.073 | 0.024 | 0.008 | 0.032 | 0.005 | 754 | 498 | 1029 | — | — |
| | | 1 hour | | | | | | | | | | | | |
| Embodiment 7 | 99.0 | 540° C. | 0.302 | 1.004 | 0.073 | 0.024 | 0.008 | 0.032 | 0.005 | 754 | 498 | 1029 | — | — |
| | | 1 hour | | | | | | | | | | | | |
| Comparative | 99.8 | 400° C. | 0.084 | 0.092 | 0.007 | 0.001 | 0.004 | 0.005 | 0.001 | 276 | — | — | 240 | — |
| Example 1 | | 1 hour | | | | | | | | | | | | |
| Comparative | 99.0 | 400° C. | 0.303 | 0.459 | 0.072 | 0.024 | 0.008 | 0.036 | 0.006 | 596 | 390 | — | 729 | — |
| Example 2 | | 1 hour | | | | | | | | | | | | |
| Comparative | 99.0 | 600° C. | 0.301 | 0.458 | 0.073 | 0.025 | 0.008 | 0.034 | 0.006 | 534 | 322 | 234 | 531 | — |
| Example 3 | | 1 hour | | | | | | | | | | | | |
| Comparative | 99.0 | 400° C. | 0.303 | 0.459 | 0.072 | 0.024 | 0.008 | 0.036 | 0.006 | 596 | 390 | — | 729 | — |
| Example 4 | | 1 hour | | | | | | | | | | | | |

| | | | Leak |
|---|---|---|---|
| | | | Current |
| | Acid used | Insulation | Density |
| | during | Failure | (A/cm²) |
| | anodization | Voltage | (200 V, 60 sec) |
| Embodiment 1 | Oxalic Acid | ≧1000 V | 1.1 · 10⁻⁷ |
| Embodiment 2 | Oxalic Acid | ≧1000 V | 7.5 · 10⁻⁸ |
| Embodiment 3 | Oxalic Acid | ≧1000 V | 2.2 · 10⁻⁷ |
| Embodiment 4 | Oxalic Acid | ≧1000 V | 6.6 · 10⁻⁷ |
| Embodiment 5 | Oxalic Acid | ≧1000 V | 7.2 · 10⁻⁷ |
| Embodiment 6 | Oxalic Acid | ≧1000 V | 8.5 · 10⁻⁷ |
| Embodiment 7 | Sulfuric Acid | ≧1000 V | 1.5 · 10⁻⁶ |
| Comparative | Oxalic Acid | 600 V | 5.1 · 10⁻⁶ |
| Example 1 | | | |
| Comparative | Oxalic Acid | 330 V | 1.6 · 10⁻⁵ |
| Example 2 | | | |
| Comparative | Oxalic Acid | 420 V | 9.6 · 10⁻⁶ |
| Example 3 | | | |
| Comparative | Sulfuric Acid | 360 V | 3.3 · 10⁻⁵ |
| Example 4 | | | |

What is claimed is:

1. An Al base material to be utilized in a method for forming a metal substrate with an insulating layer for a semiconductor element, by performing anodic oxidation on at least one surface thereof, characterized by:
precipitous particles of only a substance which is capable of being anodized by anodic oxidation being included as precipitous particles within an Al matrix.

2. An Al base material as defined in claim 1, characterized by:
the substance which is anodized being an intermetallic compound that includes one of Al and Mg.

3. An Al base material as defined in claim 1, characterized by:
metallic Si being substantially not included as precipitous particles within the Al base material.

4. A metal substrate having an insulating layer, characterized by:
an anodized film being formed on at least one surface of an Al base material as defined in claim 1, by anodic oxidation being performed on the at least one surface of the Al base material.

5. A semiconductor element, characterized by comprising:
the metal substrate having an insulating layer as defined in claim 4;
a semiconductor layer provided on the metal substrate; and
at least one pair of electrodes for applying voltages to the semiconductor layer.

6. A semiconductor element as defined in claim 5, characterized by:
the semiconductor layer being a photoelectric converting element that has a photoelectric converting function, in which electric currents are generated by the semiconductor layer absorbing light.

7. A semiconductor element as defined in claim 6, characterized by:
the main component of the semiconductor layer being a compound semiconductor having at least one type of chalcopyrite structure.

8. A semiconductor element as defined in claim 7, characterized by:
the main component of the semiconductor being at least one type of compound semiconductor comprising Ib group elements, IIIb elements, and VIb elements.

9. A semiconductor element as defined in claim 8, characterized by:
the main component of the semiconductor being at least one type of compound semiconductor, comprising:
at least one Ib group element selected from a group consisting of Cu and Ag;
at least one IIIb group element selected from a group consisting of Al, Ga, and In; and
at least one VIb group element selected from a group consisting of S, Se, and Te.

10. A solar battery characterized by being equipped with a semiconductor element as defined in claim 6.

11. A method for producing an Al base material, comprising the steps of:
preparing the Al base material;
administering melt treatment on the Al base material to obtain an Al ingot;
isothermally heating the Al ingot at a temperature less than the cocrystallization temperature of Si—Al;
cooling the Al ingot to a temperature at which rolling is possible;
rolling the Al ingot;
administering a heating process on the rolled Al at the temperature less than the cocrystallization temperature;
cold rolling the heat treated Al base material, to obtain an Al substrate; and
administering anodic oxidation onto the Al substrate from the side of at least one of the surfaces thereof.
